(19) United States
(12) Patent Application Publication
(10) Pub. No.: US 2014/0245955 A1
(43) Pub. Date: Sep. 4, 2014

(54) INJECTION SYSTEM FOR AN APPARATUS FOR DEPOSITING THIN LAYERS BY VACUUM EVAPORATION

(71) Applicant: RIBER, Bezons (FR)

(72) Inventors: Jean-Louis Guyaux, Chilly Mazarin (FR); Jerome Villette, Le Plessy Robinson (FR); Nicolas Briant, Roissy en Brie (FR); David Esteve, Bougival (FR)

(21) Appl. No.: 14/350,104

(22) PCT Filed: Oct. 18, 2012
(86) PCT No.: PCT/FR2012/052388

§ 371 Date: Apr. 7, 2014

(51) Int. Cl. C23C 14/22

(52) U.S. Cl. CPC C23C 14/228
USPC 118/715

(57) ABSTRACT

An injection system for an apparatus for depositing thin layers by vacuum evaporation includes a container (4) for receiving a material to be evaporated, container heating elements adapted to evaporate the material, at least one injection ramp (1) including an inner conduit connected to the container so as to receive the evaporated material and a plurality of nozzles (3), each nozzle including at least a communication channel so as to diffuse the evaporated material into the vacuum evaporation chamber. The injection ramp (1) includes a plurality of injection modules (2a, 2b, 2c, 2d, 2e) mechanically connected to each other in series along a longitudinal direction (5), each injection module including a plurality of injection nozzles, and the injection ramp includes elements for adjusting the orientation of the injection modules about the longitudinal direction so as to align the injection nozzles along a line parallel to the longitudinal direction.

The present invention relates to an injection system for a device for vacuum evaporation deposition, also called PVD, for Physical Vapor Deposition.

Devices for vacuum deposition of materials evaporated from a solid source of material are known. Such devices are used in particular for the manufacturing of stacks of thin layers on large substrates. For example, such devices are used for the manufacturing of solar panels of the CIGS (Copper Indium Gallium Selenium) type or of diodes of the OLED (Organic Light Emitting Devices) type. The PVD vacuum deposition devices generally comprise a source of evaporation connected to a vacuum deposition chamber. The source of evaporation makes it possible to evaporate or to sublimate the material, which is transferred in gaseous form into the vacuum deposition chamber, where it is deposited on a substrate.

The known vacuum deposition devices generally comprise an injector placed between the source of evaporation and the substrate. The injector makes it possible to diffuse the evaporated material in order to obtain a uniform deposition on a large substrate. The geometry of the injector depends on the shape and the size of the substrate. For large rectangular substrates, an injector is used, which is formed of an elongated conduit comprising openings, also called injection nozzles, for uniformly diffusing the evaporated material along the injector. The length of the injector is at least equal to the width or the length of a substrate. A relative motion between the substrate and the injector allows depositions over very large surfaces (higher than 1 m²).

An injector provided with injection nozzles arranged along the injector is also known. Each nozzle generally comprises a channel connecting the inner conduit of the injector to the vacuum deposition chamber. The shape and size of the nozzles make it possible to adapt the flow rate and the distribution of the flow of evaporated material on the surface of the substrate.

A vacuum evaporation chamber may be configured so as to allow the deposition on a single substrate or on several substrates placed in a same deposition chamber. However, the change of size of substrate or of number of substrate to be processed generally requires a change of injector so as to adapt to the configuration of the substrate and to avoid the material losses by deposition in the vacuum deposition chamber out of the substrates.

In this case, it is necessary to have several injectors each adapted to a particular configuration. Hence, it is for example provided as many injectors as there are substrate widths. But each injector is expensive. Moreover, it is required to regularly clean the injector to avoid the accumulation of internal coatings in the injector and/or in the nozzles. This cleaning operation requires a shutdown of the vacuum deposition machine, whose duration has to be as short as possible.

One of the objects of the invention is to ensure a good quality of deposition of thin layers by PVD, including thickness uniformity and physico-chemical composition of the layers for widths from 1.5 to 1.8 m.

It is desirable that the configuration of a vacuum evaporation deposition chamber can be more easily adapted so as to accept substrates of different sizes, without increasing the cost of the device.

It is also desirable to minimize the duration of shutdown of a vacuum evaporation chamber to improve the efficiency of the evaporation device.

The present invention has for object to remedy the drawbacks of the prior arts and relates more particularly to an injection system for a device for depositing thin layers by vacuum evaporation, said injection system being intended to be placed in a vacuum evaporation chamber, and said injection system comprising a container for receiving a material to be evaporated, container heating means adapted to evaporate said material, at least one injection ramp comprising an inner conduit connected to the container so as to receive said evaporated material coming from the container and a plurality of nozzles, each nozzle comprising at least one communication channel between said inner conduit and the outer portion of the ramp, so as to diffuse the evaporated material into said vacuum evaporation chamber.

According to the invention, the injection ramp comprises a plurality of injection modules mechanically connected to each other in series along a longitudinal direction, each injection module comprising a plurality of injection nozzles, and said injection ramp comprises means for adjusting in orientation said injection modules about said longitudinal direction so as to align said injection nozzles of said injection modules along a line parallel to the longitudinal direction of the injection ramp.

According to a particular embodiment of the invention, said injection modules are cylindrical in shape, the injection nozzles of an injection module being arranged on a generating line of said cylinder.

According to different aspects of the invention:
said injection modules have an identical structure, the injection ramp further comprising a shutter module adapted to tightly close an end of the injection ramp;
said container is formed of at least one first cylindrical container module adapted to be fixed on a first injection module at a first open end of the injection ramp and/or of a second cylindrical container module adapted to be fixed on a last injection module at a second open end of the injection ramp;
the material of the injection modules is one of the following materials: alumina (Al₂O₃), graphitic carbon, glassy carbon, carbon coated with pyrolytic graphite, purified carbon, carbon coated with silicon carbide or pyrolytic boron nitride (or PBN).

According to different aspects of embodiments of the invention, the injection system further comprises:
at least one compression sealing gasket, said sealing gasket being adapted to ensure the alignment of the nozzles when compressed;
said at least one sealing gasket being made of flexible graphite;
said at least one sealing gasket being arranged between two adjacent injection modules and/or between the container module and the first injection module and/or between the last injection module and a shutter module;
independent heating means associated with each injection module and/or with the container module, said heating means comprising two semi-cylindrical half-shelves adapted to envelop said injection module, respectively said container module;
thermal shielding means arranged around the heating means and cooling means arranged around the thermal shielding means;
a frame and mechanical means for the fixation of the plurality of injection modules and/or of the container module to said frame;
said frame comprises one or several rectilinear bars, said fixation means being mounted so as to be able to slide along said bar(s).

The invention also relates to an injection system comprising a plurality of injection ramps according to one of the embodiments described, the longitudinal axes of said injection ramps being arranged parallel to each other to allow a uniform co-evaporation of materials.

The invention will find a particularly advantageous application in an injection device for a vacuum evaporation deposition system, in particular for the manufacturing of OLEDs.

The present invention also relates to the characteristics that will become more apparent from the following description and that will have to be considered in isolation or according to any of their technically possible combinations.

This description, which is given only by way of non-limitative example, will allow a better understanding of how the invention can be implemented with reference to the appended drawings, in which:

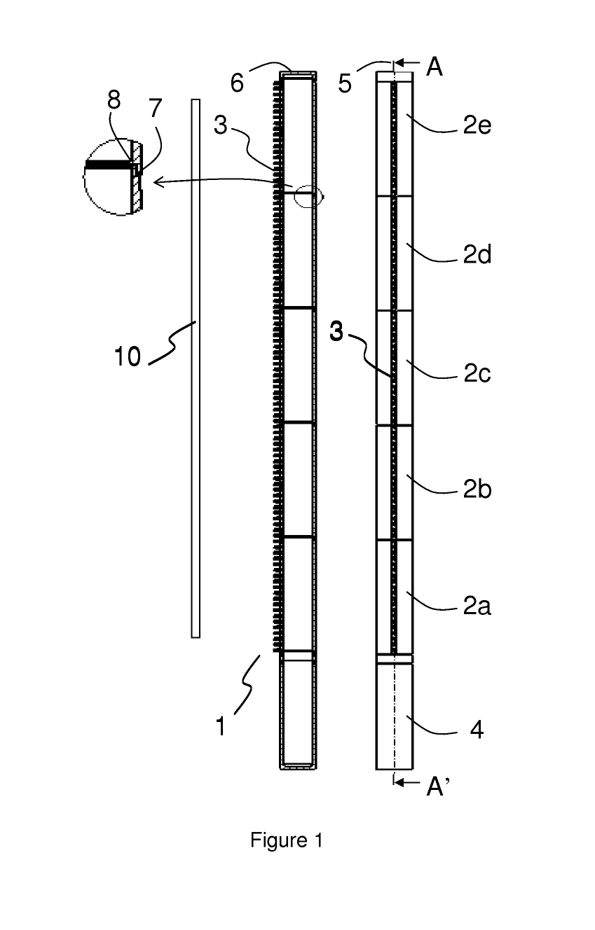

FIG. 1 shows an injection ramp, in front view and in longitudinal section according to a first embodiment of the invention;

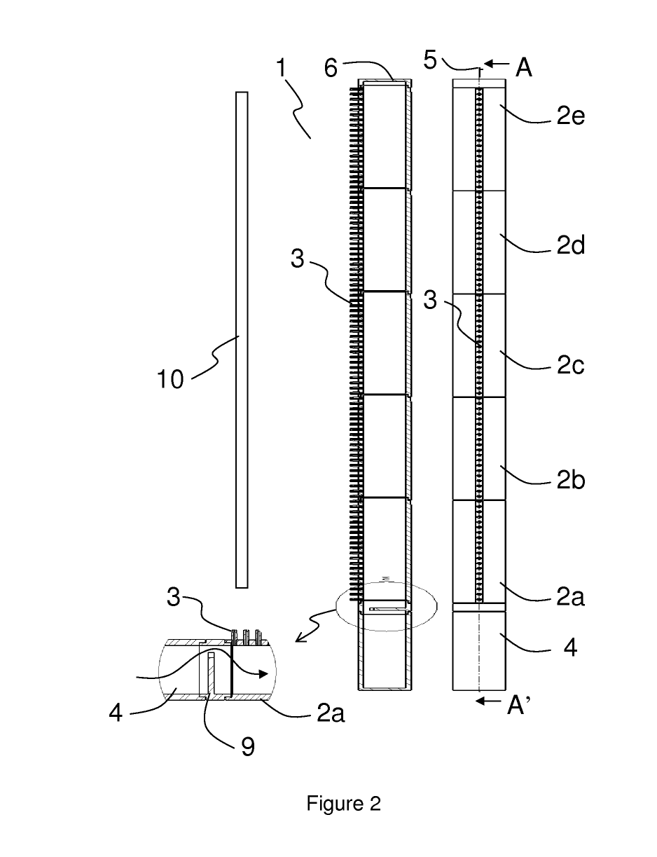

FIG. 2 shows an injection ramp, in bottom view and in longitudinal section according to a second embodiment of the invention;

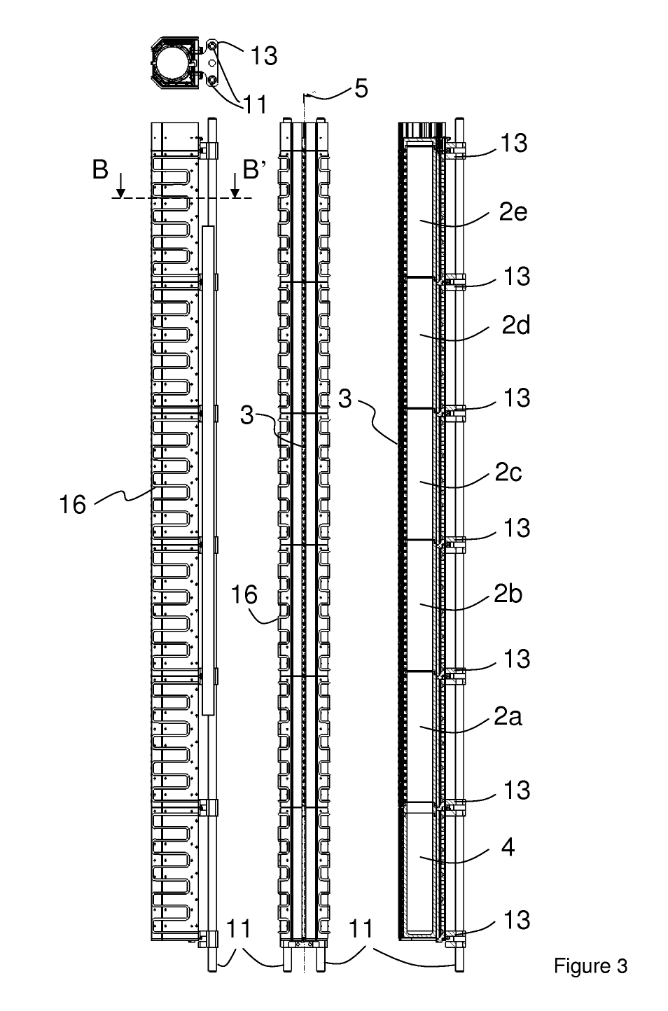

FIG. 3 shows an injection ramp, in front view, side view, axial section and longitudinal section;

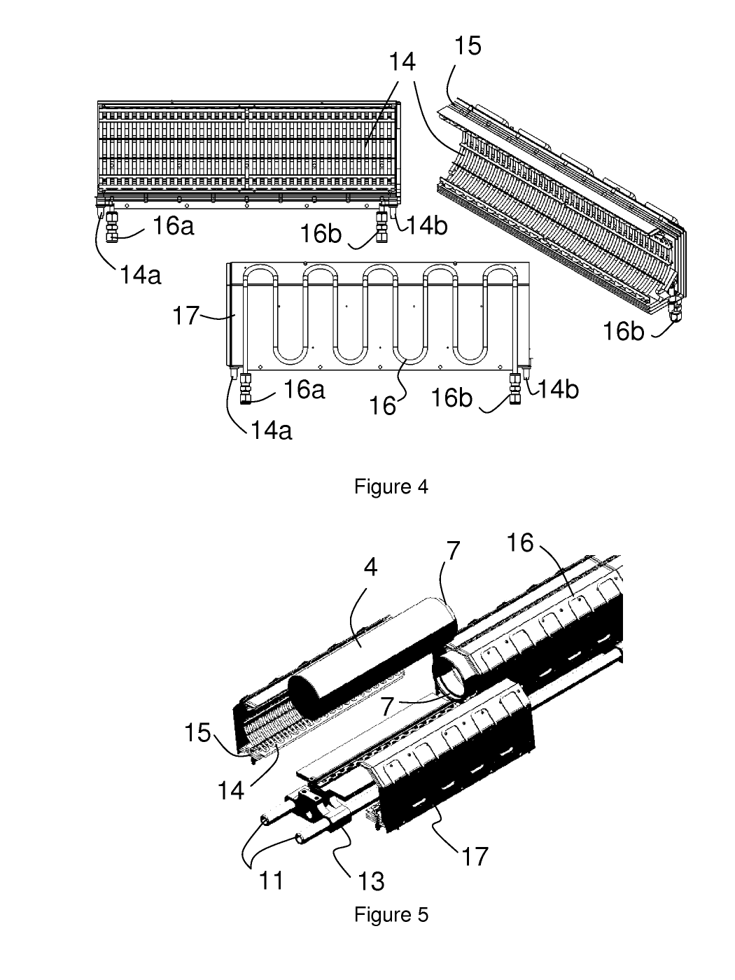

FIG. 4 shows a front and perspective view of a thermal shelf intended to envelop a module of an injection ramp according to a particular embodiment of the invention;

FIG. 5 schematically shows a perspective view of an injection ramp during the mounting/dismounting of a container according to a particular embodiment;

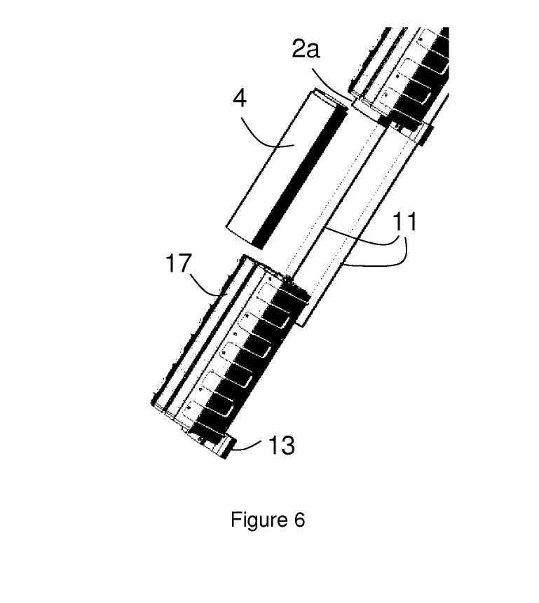

FIG. 6 schematically shows a perspective view of an injection ramp during the mounting/dismounting of a container according to another particular embodiment;

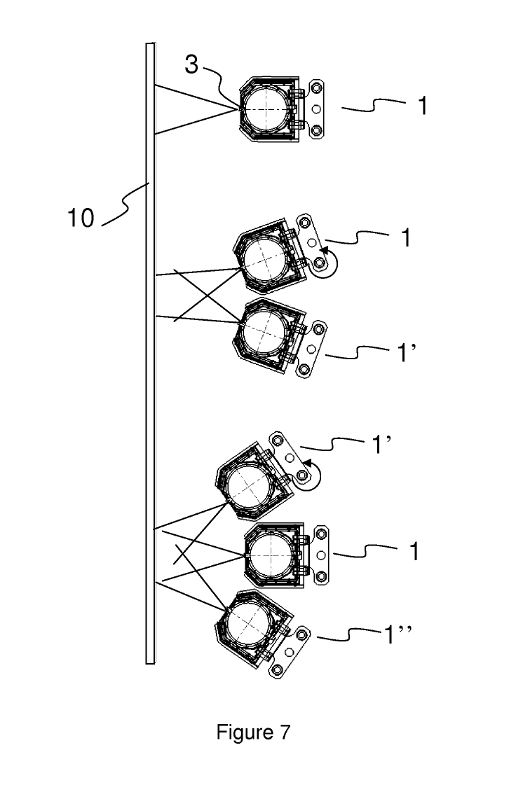

FIG. 7 schematically shows, in side view, different configurations of deposition based on the use of a single injection ramp for the mono-evaporation and of two and three injection ramps for the co-evaporation, respectively.

The invention relates to an injection ramp for a vacuum evaporation deposition system, the injection ramp being adapted to receive materials vaporized from a source of evaporation. In a manner known per se, a ramp comprises a diffuser provided with a plurality of nozzles to diffuse the vaporized material into a vacuum deposition chamber. The evaporation chamber in which are placed the substrate and the injection ramp is not shown in FIGS. 1 to 6.

FIG. 1 schematically shows an injection ramp according to a first embodiment of the invention. The right portion of FIG. 1 shows in front view an injection ramp 1. In the left portion of FIG. 1 is shown a substrate 10 on which it is desired to deposit a material and the injection ramp 1, in longitudinal section along the direction AA′. As an insert, in the left portion of FIG. 1, is shown a magnification of a detail of the sectional view of the ramp.

Firstly, the front view of the injection ramp of FIG. 1 will be described in detail. The injection ramp extends along a longitudinal axis 5. The injection ramp 1 comprises a container module 4 intended to contain the material to be evaporated. The material to be evaporated may be in different forms (liquid, solid, powder . . . ). In particular, the container is intended to evaporate the following materials: silver (Ag), magnesium (Mg), gallium (Ga), indium (In), lithium fluoride (LiF), indium sulfide (In₂S₃), zinc (Zn), cadmium (Cd), tin (Sn), aluminum (Al) or copper (Cu). According to the embodiment of FIG. 1, the injection ramp 1 is mainly intended to be mounted vertically. In this case, the container module 4 is positioned at the lower end of the ramp so as to contain the non-evaporated material by gravity. In the example shown in FIG. 1, the container module is in the alignment of the ramp. However, the container module 4 may have a peculiar geometry, disposition (in line, at 45°, at 90° with respect to the longitudinal axis 5) or also capacity (length, diameter) according to the operation (horizontal or vertical), the material to be evaporated, the duration of production of the injection system or also the consumption of material to be evaporated.

The injection ramp 1 also includes several injection modules 2a, 2b, 2c, 2d, 2e mounted in series. The example shown includes five injection modules. However, the number of injection modules is of course not limited. The first injection module 2a is fixed on the container module 4. The injection module 2b is fixed on an injection module 2a. Likewise, the injection module 2c is fixed on an injection module 2b, etc . . . Finally, a shutter module 6 is fixed on the injection module 2e. The end of the ramp 1 opposed to the container module 4 is hence closed by the shutter module 6 tight against the vapor of said material to be evaporated. The shutter module 6 may be integrated to end injection module so as to form only one injection module closed at one end. The different injection modules forming the ramp may be fixed to each other, for example by nesting or by screwing. The injection modules are orientable about their axis so as to allow an angular adjustment of each injection module. This adjustment in orientation allows ensuring the alignment of the nozzles along the ramp, this alignment being critical for the quality of the coatings. In the case where the injection modules are screwed to each other, each injection module includes an adapted thread 7. During the machining of a module, the starting position of the thread is controlled with respect to the position of the nozzles, which gives a coarse alignment, the fine alignment being ensured by the compression of a sealing gasket. Preferably, a sealing gasket 8 is arranged between two injection modules. The gasket ensures the tightness of the fixation relative to the vacuum evaporation chamber while allowing the adjustment in orientation of the injection modules.

As can be observed on the sectional view of FIG. 1, the container module 4 and the injection modules 2a, 2b, 2c, 2d, 2e are tubular and hollow in shape. The injection modules are cylindrical, the nozzles being aligned on a generating line of the cylinder. According to a preferred embodiment, the injection modules have an almost-circular section but include a flat that carries the nozzles.

The injection module 2a communicates with the container 4 through a central opening. The injection module 2b also communicates with the injection module 2a through a central opening and so on to the injection module 2e and the shutter module 6. The evaporated material emerging from the container can then diffuse freely inside all the modules of the injection ramp to the shutter module. The inner diameter of the different modules of the injection ramp is sufficient so that its conductance ensures a low or negligible loss of charge, hence ensuring an identical flow on each nozzle.

Each injection module 2a, 2b, . . . 2e is provided with a plurality of injection nozzles 3. A nozzle 3 generally comprises a channel connecting the interior of the ramp to the evaporation chamber to allow the diffusion of the evaporated material toward the substrate 10. Preferably, the nozzles 3 of the different modules are aligned along an axis parallel to the axis 5 of the ramp. According to an exemplary embodiment, each injection module 2 includes about twenty nozzles 3. According to a preferred embodiment, the nozzles are distributed with a constant interval between consecutive nozzles so as to obtain a spatially uniform distribution of the nozzles 3 along an axis parallel to the axis 5. According to a preferred embodiment, each nozzle is consisted by an added element, for example screwed to the injection module. In this case, a nozzle is interchangeable with a nozzle having a different opening. Hence, it is possible to place nozzles 3 having different openings according to the position of the nozzle 3 along the ramp 1, so as to adjust the deposition profile over the whole surface of the substrate 10. According to an exemplary embodiment, the length of an injection module 2a is equal to 400 mm, the accuracy of orientation by rotation about the longitudinal axis being lower than 2 degrees, the inter-nozzle space is equal to 20 mm, and the thread 7 extends over 10 mm long.

Preferably, the injection modules, the shutter module and/or the container module are manufactured in a material that has a chemical compatibility with the material to be evaporated at the desired evaporation temperature. For example, the material of the injection modules of the container module and/or of a shutter module may be carbon, graphite, pyrolytic graphite, glassy carbon, boron nitride, alumina . . . A sealing washer 8 in flexible graphite of the order of 1 mm thick is interposed between two adjacent modules to ensure the tightness and also to allow adjusting the orientation of the different injection modules 2a, 2b . . . and thus allow aligning the nozzles 3.

As detailed hereinabove, the ramp 1 is hence consisted of different modules connected in series to form a linear cell along the axis 5: container module, injection modules and shutter module. The number of injection modules determines the length of the ramp and is easily reconfigurable.

FIG. 2 shows a second embodiment of injection ramp, more particularly intended to be mounted horizontally along the axis 5. The right portion of FIG. 2 shows a bottom view of an injection ramp 1. In the left portion of FIG. 2 is shown a substrate 10 on which it is desired to deposit a material and the injection ramp 1, in longitudinal section along a section AA′. As an insert is shown a magnification of a detail of the sectional view of the ramp. The same reference signs indicate the same elements as in FIG. 1. The ramp of FIG. 2 also includes a container module 4, several injection modules 2a, 2b, 2c, 2d, 2e mounted in series and provided with injection nozzles 3, and a shutter module 6. As an insert is shown a sectional view of an intermediate module located between the container module 4 and the first injection module 2a. The intermediate module is fixed on the one hand to the opening of the container and on the other hand to the first injection module 2a. The intermediate module 9 includes an inner wall that partially shuts the inner opening of the ramp so as to contain the non-evaporated material in the container. The inner wall includes an opening intended to let through the flow of evaporated material (schematically shown by an arrow in the insert of FIG. 2). This intermediate module 9 with an inner wall is particularly adapted in the case where the container module is aligned horizontally to allow the non-evaporated material to be maintained in the container module 4. The intermediate module is orientable by rotation about the axis 5 of the ramp, so that the opening of the inner wall is located in the upper portion of the ramp, as shown in the insert, in the case where the nozzles are oriented upward.

FIG. 3 shows different views of an injection ramp provided with heating means to allow the evaporation and the diffusion of material. A ramp is shown at the center of FIG. 3 in front view, on the left of FIG. 3 in side view, on the right of FIG. 3 in longitudinal sectional view along the axis 5 and on the top left of FIG. 3 in axial sectional view along the section plane BB′. The ramp comprises the different modules as described in connection with FIG. 1, in particular a container module 4, several injection modules 2a, . . . , 2e and an end module 6. The container module 4, as well as each injection module is enveloped by a thermal shell. Each thermal shell has the same length as the container module or injection module it envelops. It is observed on the face and side views, external cooling means of the thermal shells, in the form of coils 16 provided for the circulation of a cooling fluid, for example water. The injection ramp is mounted on a frame comprising two cylindrical bars 11, the bars 11 being parallel between each other and parallel to the axis 5 of the ramp. The ramp 1 is fixed on the frame by means of fixation tabs 13. Advantageously, the fixation tabs 13 are adjustable by sliding along the axis of the bars 11.

Preferably, a thermal shell is consisted of two half-shells of generally semi-cylindrical shape and intended to envelop a ramp of also cylindrical outer shape. The two half-shells forming a thermal shell are symmetrical with respect to a plane passing through the longitudinal axis 5 of the ramp. FIG. 4 shows a front face view, a rear face view and a perspective view of a thermal half-shell intended to envelop a module of an injection ramp according to a particular embodiment. The half-shell 17 comprises on its inner face a filament 14 intended to heat by radiation a module of the ramp. The filament 14 makes it possible to bring the injection ramp to a temperature that can reach 1200° C. to 1500° C. The half-shell 17 includes electrical connectors 14a, 14b at both ends of the filament 14. Each thermal half-shell can hence be connected to an electric power source, independently from the other thermal shells. Each thermal half-shell can also be connected in series with the other thermal shells to a single electric power source. The filament is protected against the environment of the ramp by a thermal shield 15. A water-cooling system 16 placed on the outer portion of the shell 17 allows reducing the outer temperature of the ramp. The cooling system 16 includes connectors 16a, 16b for fluidic connection to the two ends of the cooling circuit of a half-shell. Each thermal half-shell may then be connected to a source of cooling water independently from the other thermal half-shells. Each thermal half-shell may also be connected in series with the other thermal half-shells to a single source of cooling water.

It is required to proceed to the filling of the container module once the material is consumed. It may be necessary to proceed to the replacement of the container in a maintenance operation. FIG. 5 schematically shows a perspective view of an injection ramp during the mounting/dismounting of a container according to a particular embodiment. In this embodiment, the two thermal half-shells 17 that envelop the container module are detached. The container module 4 is thus accessed. The container module is nested or screwed by threads 7 on the first injection module 2a. This system allows leaving the injection ramp in place in the evaporation chamber. Moreover, the container change may be made very rapidly.

FIG. 6 schematically shows a perspective view of an injection ramp during the mounting/dismounting of a container according to another particular embodiment. In this case, the thermal shell enveloping the container module is not dismounted, but simply displaced by releasing the fixation tab 13 then by sliding the thermal shell along the bars 11 of the frame. The cleared space allows having access to the container, to fill or to replace it. During the reassembling, it is sufficient to fix the container module 4 on the first injection module 2a, and to slide the shell 17 along the bars 11 so that it envelops the container module 4. The fixation tabs may be held by screws.

It is also contemplated to proceed to the filling of the container without dismounting the container module nor the thermal shell. For example, it is possible to dismount only an end module 6, without having to dismount a thermal shell. It is then possible to proceed to the filling of the container at the other end of the injection ramp, by suitable means, such as a spout or a “charging pipe line”. An alternative solution consists in sliding an open container (commonly called a “boat”) in the injection ramp from the end that is opposed to the container module. This latter configuration seems to be more in adequacy with an horizontal operation of the ramp. This container contains the material to be evaporated.

The frame ensures the rigidity of the whole injection ramp 1. More over, the frame allows interfacing the injection ramp with a transfer system to produce a movement of the ramp with respect to large substrates. Finally, the frame allows to easily orient one or several injection ramps with respect to the plane of a substrate. Therefore, FIG. 7 illustrates different configurations of deposition. At the top of FIG. 7 is illustrated the use of a single injection ramp for the mono-evaporation from a container of material. At the center of FIG. 7 is shown a system with two injection ramps 1 and 1′. Each of the two injection ramps 1, 1′ includes its proper container of material. This system with two injection ramps easily allows the co-evaporation of different materials, that are deposited at the same moment on the substrate. The bars 11 of each ramp allow by simple rotation about a bar to orient each ramp, for example in a manner that is symmetrical with respect to the normal to the substrate. The two ramps have advantageously the same length, are parallel to each other, and parallel to the plane of the substrate which allows obtaining an homogeneous co-evaporation over the whole length of the ramps 1 and 1′. Similarly, a system with three injection ramps 1, 1′, 1″ is shown at the bottom of FIG. 7. Each of the three injection ramps 1, 1′, 1″ includes its own container of material, to allow the co-evaporation of three different materials, deposited simultaneously on the substrate 10. Advantageously, the three ramps have the same length, are arranged parallel to each other and parallel to the plane of the substrate 10, to allow a uniform co-evaporation.

The construction of the injection ramp by assembling different modules (injection modules, container module) allows adapting easily to the size of the substrate to be processed and in particular to substrates of great size. The manufacturing of a ramp of particular length is based on the assembling of a predetermined number of injection modules, but requires no study nor specific tool, and is hence of lesser cost. On the other hand, the container module is easy to load and unload, which allows reducing the time during which the device is shutdown, and thus to improve the efficiency of the vacuum evaporation machine. The linear construction of the injection ramp allows contemplating uniform co-evaporation configurations with two or three injection ramps, or even more.

1. An injection system for a device for depositing thin layers by vacuum evaporation, said injection system being intended to be placed in a vacuum evaporation chamber, and said injection system comprising:
a container (4) for receiving a material to be evaporated,
container heating means adapted to evaporate said material,
at least one injection ramp (1) comprising an inner conduit connected to the container (4) so as to receive said evaporated material coming from the container (4) and a plurality of nozzles (3), each nozzle (3) comprising at least one communication channel between said inner conduit and the outer portion of the ramp, so as to diffuse the evaporated material into said vacuum evaporation chamber,
characterized in that:
the injection ramp (1) comprises a plurality of injection modules (2a, 2b, 2c, 2d, 2e) mechanically connected to each other in series along a longitudinal direction (5), each injection module (2a, 2b, 2c, 2d, 2e) comprising a plurality of injection nozzles (3), and
said injection ramp (1) comprises means for adjusting in orientation said injection modules (2a, 2b, 2c, 2d, 2e) about said longitudinal direction (5) so as to align said injection nozzles (5) of said injection modules (2a, 2b, 2c, 2d, 2e) along a line parallel to the longitudinal direction (5) of the injection ramp (1).

2. The injection system according to claim 1, wherein said injection modules (2a, 2b, 2c, 2d, 2e) are cylindrical in shape, the injection nozzles (3) of an injection module (2a, 2b, 2c, 2d, 2e) being arranged on a generating line of said cylinder.

3. The injection system according to claim 2, wherein said injection modules (2a, 2b, 2c, 2d, 2e) have an identical structure, the injection ramp further comprising a shutter module (6) adapted to tightly close an end of the injection ramp.

4. The injection system according to claim 1, wherein said container is formed of at least one first cylindrical container module (4) adapted to be fixed on a first injection module at a first open end of the injection ramp and/or of a second cylindrical container module adapted to be fixed on a last injection module at a second open end of the injection ramp.

5. The injection system according to claim 1, wherein the material of the injection modules (2a, 2b, 2c, 2d, 2e) is one of the following materials: alumina (Al₂O₃), graphitic carbon, glassy carbon, carbon coated with pyrolytic graphite, purified carbon, carbon coated with silicon carbide or pyrolytic boron nitride.

6. The injection system according to claim 1, further comprising at least one compression sealing gasket arranged between two adjacent injection modules (2a, 2b, 2c, 2d, 2e) and/or between the container module (4) and the first injection module (2a) and/or between the last injection module (2e) and a shutter module (6), said at least one sealing gasket being adapted to ensure the alignment of the nozzles when compressed.

7. The injection system according to claim 1, further comprising independent heating means (14) associated with each injection module and/or with the container module, said heating means (14) comprising two semi-cylindrical half-shelves adapted to envelop said injection module (2a, 2b, 2c, 2d, 2e), respectively said container module (4).

8. The injection system according to claim 7, wherein the half-shells further comprise thermal shielding means (15) arranged about heating means (14) and cooling means (16) arranged about thermal shielding means (15).

9. The injection system according to claim 1, further comprising a frame (11) and means (13) for the mechanical fixation of the plurality of injection modules (2a, 2b, 2c, 2d, 2e) and/or of the container module (4) to said frame.

10. The injection system according to claim 9, wherein said frame comprises one or several rectilinear bars (11), said fixation means being mounted so as to be able to slide along said bar(s) (11).

11. The injection system according to claim 1, comprising a plurality of injection ramps, the longitudinal axes (5) of said injection ramps being arranged parallel to each other to allow a uniform co-evaporation of the materials.
